(19) United States
(12) Patent Application Publication
(10) Pub. No.: US 2025/0174472 A1
(43) Pub. Date: May 29, 2025

(54) STAINLESS STEEL MEMBER FOR APPARATUS FOR MANUFACTURING SEMICONDUCTOR AND METHOD FOR MANUFACTURING THE SAME

(71) Applicants: ORORU inc., Tottori (JP); TOTTORI INSTITUTE OF INDUSTRIAL TECHNOLOGY, Tottori (JP)

(72) Inventors: Kazuyoshi KAWAMI, Tottori (JP); Atsushi KINOSHITA, Tottori (JP); Naoto OSAKI, Tottori (JP); Naofumi TERADA, Tottori (JP); Toshiyuki TANAKA, Tottori (JP)

(21) Appl. No.: 18/961,810

(22) Filed: Nov. 27, 2024

(30) Foreign Application Priority Data
Nov. 28, 2023 (JP) 2023-200418

(51) Int. Cl. H01L 21/67; C25D 5/00; C25D 5/36; C25D 5/48; C25F 3/24

(52) U.S. Cl. CPC H01L 21/67023; C25D 5/36; C25D 5/48; C25D 5/627; C25F 3/24

(57) ABSTRACT

Provided is a chromium oxide film-coated stainless steel member containing metal impurities at a small amount and having high heat-retaining properties. A chromium oxide film-coated stainless steel member wherein the thickness of a chromium oxide film is 190 to 280 nm, and the maximum value of the surface reflectance in the near-infrared region (at a wavelength of 750 to 2500 nm) is 60% or less. The chromium oxide film-coated stainless steel member is manufactured by a precise electropolishing step and a step of coating the stainless steel member with a chromium oxide film. The precise electropolishing step comprises pulse voltage impression, microaeration, and electrolyte jetting. The height difference of the polished surface of the stainless steel measured with a scanning probe microscope is 30 nm or less.

### CROSS REFERENCE TO RELATED APPLICATIONS

This application claims the benefit of Japanese Patent Application No. 2023-200418, filed Nov. 28, 2023, which is hereby incorporated by reference in its entirety.

### BACKGROUND

### Technical Field

The present disclosure relates to a stainless steel member for an apparatus for manufacturing a semiconductor and a method for manufacturing the stainless steel member. The present disclosure relates especially to a stainless steel member for an apparatus for manufacturing a semiconductor wherein the stainless steel member is a stainless steel member surface-smoothed by electropolishing and coated with a metal oxide film formed by a wet process, and a method for manufacturing the stainless steel member.

### Background

In the manufacturing of semiconductor devices, for example, a thin film formation step, a lithography step, an etching step, and a flattening step are repeated. These steps are performed in an ultra-vacuum or under reduced pressure, and various semiconductor-treating liquids are used.

It is required that metal impurities generated from members for apparatuses for manufacturing semiconductors or metal impurities contained in semiconductor-treating liquids be controlled to the ppt level in conjunction with the micronization of the semiconductor design rule.

Since maintaining high temperature is needed in processes for manufacturing semiconductor devices, members having high heat-retaining properties have been required for apparatuses for manufacturing semiconductors.

International Publication No. WO 1992/021786 discloses a method for forming a passive film on stainless steel, comprising electropolishing the surface of stainless steel, followed by oxidation in an acidic atmosphere and removing iron oxide from the surface with hydrogen gas by reduction, and a fluid contact part of stainless steel having a passive film with a surface roughness (Rmax) of 0.1 μm or less on the surface.

International Publication No. WO 2019/167885 discloses an austenitic stainless steel member having a passive layer with a film thickness of 2 to 20 nm on the surface of a base material made of austenitic stainless steel and an apparatus including liquid contact portions for contact with a semiconductor-treating liquid formed of the austenitic stainless steel member.

Japanese Patent Application Laid-Open No. 2005-247629 discloses an ingot-manufacturing apparatus electropolished or chemically polished so as to enhance the heat absorptivity by blackening, and blackened by the INCO process or by electrolytic coloring.

Japanese Patent No. 7029742 discloses an electropolishing liquid for stainless steel, exclusively consisting of phosphoric acid and at least one organic sulfonic acid, wherein the electropolishing liquid enables reducing the viscosity of an anolyte layer formed near a metal to be polished (Jacquet layer) in the electropolishing to suppress the retention of bubbles accompanying the anode reaction on the surface of the metal to be polished, so that the progress of electrolytic processing is uniformed, and the processing precision is enhanced to improve the surface smoothness of the stainless steel as the metal to be treated; a method for electrolyzing stainless steel using the electropolishing liquid; and a method for manufacturing stainless steel in which the electrolyzed stainless steel is coated with a passive film.

The present disclosure is related to providing a chromium oxide film-coated stainless steel member that enables controlling metal impurities generated from apparatuses for manufacturing semiconductors or metal impurities contained in semiconductor-treating liquids to the ppt level and has low infrared reflectance and high heat-retaining properties and a method for manufacturing the chromium oxide film-coated stainless steel member.

### SUMMARY

In accordance with the present disclosure, the following aspects are provided.

### (Aspect 1)

Aspect 1 is a chromium oxide film-coated stainless steel member, wherein a surface of an electropolished stainless steel member is coated with a chromium oxide film, the surface of the electropolished stainless steel member has the maximum height of a contour curve (Rz) measured with a scanning probe microscope in accordance with JIS B0601-2013 of 30 nm or less, a film thickness of the chromium oxide film is 190 to 280 nm, and the maximum value of the surface reflectance in the near-infrared region (at a wavelength of 750 to 2500 nm) is 60% or less.

This is because if the film thickness of the chromium oxide film is 190 to 280 nm, the maximum value of the surface reflectance in the near-infrared region (at a wavelength of 750 to 2500 nm) can be adjusted to 60% or less.

### (Aspect 2)

Aspect 2 is a method for manufacturing a chromium oxide film-coated stainless steel member wherein a film thickness of a chromium oxide film is 190 to 280 nm, and the maximum value of surface reflectance in the near-infrared region (at a wavelength of 750 to 2500 nm) is 60% or less, comprising: an electropolishing step of electropolishing a surface of a stainless steel member with an electropolishing liquid for stainless steel at 85° C. exclusively consisting of 50% by volume phosphoric acid and 50% by volume methanesulfonic acid at a current density of 20 A/dm² for 5 minutes in combination with pulse voltage impression, microaeration, and electrolyte jetting to adjust the maximum height of a contour curve (Rz) measured with a scanning probe microscope in accordance with JIS B0601-2013 to 30 nm or less; and a step of coating the stainless steel member with a chromium oxide film, comprising: film formation involving immersing the electropolished stainless steel member in a treating liquid comprising a mixed solution of 25% w/vol chromic acid and 50% w/vol sulfuric acid to form a chromium oxide film on the surface of the stainless steel member at a coloring potential of 17 to 28 mV, and hardening involving immersing the coated stainless steel member in a treating liquid comprising a mixed solution of chromic acid and phosphoric acid to harden the chromium oxide film.

This is because the combination of any or all of the pulse voltage impression, the microaeration, and the electrolyte jetting with the electropolishing enables removing the anolyte layer (Jacquet layer) formed near a metal to be polished in the electropolishing and suppression of the retention of bubbles accompanying the anode reaction, so that the progress of electrolytic processing is uniformed, and the processing precision is enhanced to improve the surface smoothness of the stainless steel as the metal to be treated.

The present disclosure enables providing a chromium oxide film-coated stainless steel member for an apparatus for manufacturing a semiconductor wherein the chromium oxide film-coated stainless steel member generates as little metal impurities as a precisely electropolished stainless steel member generates and a method for manufacturing the chromium oxide film-coated stainless steel member.

Coating a stainless steel member with a chromium oxide film enables providing a chromium oxide film-coated stainless steel member for an apparatus for manufacturing a semiconductor wherein the member has low infrared reflectance and high heat-retaining properties, and the method for manufacturing the chromium oxide film-coated stainless steel member.

### BRIEF DESCRIPTION OF THE DRAWINGS

FIG. 1 is a process chart showing the flow of a method for manufacturing a chromium oxide film-coated stainless steel member of the present disclosure;

FIG. 2 is a schematic view showing one of the embodiments of an electropolisher for precise electropolishing of the present disclosure;

FIG. 3 is a schematic view showing a pulse waveform (voltage waveform) in pulse voltage impression of the present disclosure;

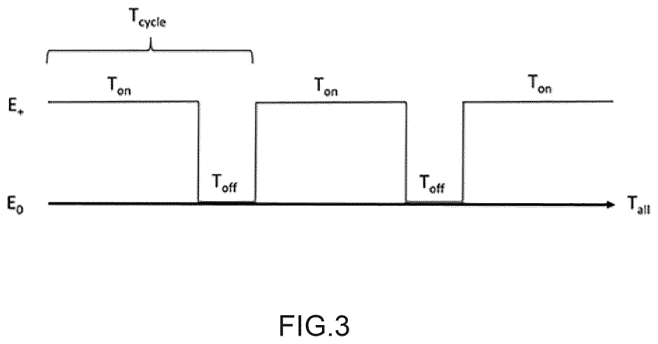

FIG. 4 is a graph showing the relationship between the coloring potential and the thickness of the chromium oxide film in an embodiment of the present disclosure;

FIG. 5 is spectral reflectance data (at 250 to 2700 nm) in an embodiment of the present disclosure;

FIG. 6 is images showing uneven surface profiles through a scanning probe microscope in an embodiment of the present disclosure; and

FIG. 7 is data showing surface element analysis by X-ray photoelectron spectroscopy in an embodiment of the present disclosure.

### DETAILED DESCRIPTION

Hereinafter, the present disclosure will be described in accordance with the embodiments. The following description is, however, for understanding the present disclosure, and does not limit the present disclosure.

### A. Chromium Oxide Film-Coated Stainless Steel Member

A chromium oxide film-coated stainless steel member of the present disclosure is a stainless steel member in which the surface of an electropolished stainless steel member is coated with a chromium oxide film. The film thickness of the chromium oxide film is 190 to 280 nm, and the maximum value of the surface reflectance in the near-infrared region (at a wavelength of 750 to 2500 nm) is 60% or less.

The film thickness of the chromium oxide film is controlled to 190 to 280 nm by the chromium oxide film formation step, described below. Controlling the film thickness to 190 to 280 nm enables adjusting the maximum value of the surface reflectance in the infrared region (at a wavelength of 750 to 2500 nm) to 60% or less.

### 1. Stainless Steel

As the stainless steel for the chromium oxide film-coated stainless steel member of the present disclosure, stainless steel that has been used as piping or container members that are the main materials in an apparatus for manufacturing a semiconductor is preferably usable. Specific examples include ferrite stainless steel, martensitic stainless steel, and austenitic stainless steel. Martensitic stainless steels (for example, 410C, 420, 430, 440C, and 440B) and austenitic stainless steels (for example, 304, 304L, 321, 347, and 316L) are preferably usable for high-pressure storage containers or high-pressure pipelines, requiring corrosion resistance or high strength.

Welded stainless steels forming the piping, the container members, and structures for manufacturing semiconductors as the main materials in the apparatus for manufacturing a semiconductor are also included in the chromium oxide film-coated stainless steel member of the present disclosure. For example, members formed of stainless steel plates are welded to form a container, followed by the pickling of the inside to manufacture a storage pressure container. Steel strips formed of stainless steel plates are passed through pipe-manufacturing and welding lines to manufacture high-pressure pipes conveying chemicals. Multiple pipes are welded to manufacture pipelines

### B. Method for Manufacturing Chromium Oxide Film-Coated Stainless Steel Member

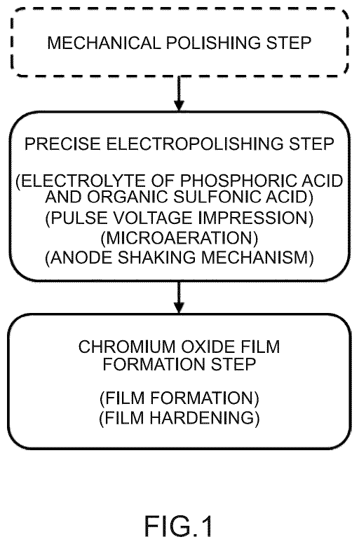

As shown in FIG. 1, the chromium oxide film-coated stainless steel member is manufactured by a precise electropolishing step of electropolishing the surface of a stainless steel member in electrolyte comprising phosphoric acid and sulfonic acid in an electrolytic cell provided with pulse voltage impression apparatus, microaeration apparatus, and electrolyte jetting apparatus and a chromium oxide film formation step of forming a chromium oxide film on the surface of the electropolished stainless steel member in a wet process and hardening the chromium oxide film. A mechanical polishing step can be performed in advance for making the electropolishing more precise and more rapid.

Hereinafter, the mechanical polishing step, the precise electropolishing step, and the chromium oxide film formation step will be described sequentially.

### 1. Mechanical Polishing Step

In the mechanical polishing step for manufacturing the chromium oxide film-coated stainless steel member of the present disclosure, buffing can be preferably adopted. This is because buffing before the electropolishing enables speeding up the electropolishing step, and improves the surface smoothness obtained by the electropolishing.

Buffing is a method for polishing using cloth or non-woven fabric having the peripheral surface covered with an abrasive. An article having a rough nonuniform surface can be polished with different types of cloth or non-woven fabric or different abrasives multiple times to perform a process from rough polishing to glossy finish.

Examples of the type of the buffs include cloth buff such as sewn buffs, stitched buffs, loose buffs, bias buffs, and sisal buffs. Examples of other buffs include flap wheels, non-woven fabric wheels, and wire wheels. These buffs are used depending on the purpose. Buffs having napped nylon fibers are preferable. Examples of the buff abrasive include a polishing material in which an abrasive that is comparatively fine powder as the main ingredient is uniformly mixed with a medium comprising oil and fat or other suitable components. As the buff abrasive of the present disclosure, a finishing abrasive #400 or a finer abrasive can be preferably adopted.

### 2. Precise Electropolishing Step

The precise electropolishing step for manufacturing the chromium oxide film-coated stainless steel member of the present disclosure has a role as pretreatment for removing or reducing an oxide film or impurities (nonmetallic inclusions) on the surface of the stainless steel member and surface defects such as damaged layers to form a uniform dense chromium oxide film on the surface of the stainless steel member.

Electropolishing is a polishing method involving passing an electric current through a metal to be polished as an anode in electropolishing liquid with an external power source to dissolve protruding parts on finely uneven surface of the metal to be polished, resulting in smoothing and shining the surface of a metal to be polished. Electropolishing is advantageous in that damaged layers or work-hardened layers are not generated, and the polished surface has less impurities, or is less contaminated unlike physical polishing such as buffing, so that the polished surface is cleaned.

An anode polarization curve (Jacquet curve) in an electropolishing bath has a certain current (limited current) range without depending on the electrode potential. A thick and highly viscous anolyte layer (Jacquet layer) is formed near the metal to be polished in this limited current range. It is conceivable that this anolyte (Jacquet layer) suppresses the diffusion of eluted cations to electropolish the metal to be polished. That is, the unevenness of the metal to be polished makes a difference in the concentration gradient in the viscous liquid layer, and the influence of a diffusion current concentrates currents on the protruding parts to remove the unevenness of the surface, resulting in polishing.

### (2-1) Electropolishing Liquid

In the electropolishing of the present disclosure, an electropolishing liquid for stainless steel exclusively consisting of phosphoric acid and methanesulfonic acid and having an electrolytic composition of 25 to 50% by volume phosphoric acid and 50 to 75% by volume methanesulfonic acid is preferable. That is, the electropolishing liquid exclusively consists of water as a solvent, and phosphoric acid and methanesulfonic acid as solutes. This is because changing a solute in the electropolishing liquid from sulfuric acid, having high viscosity, to methanesulfonic acid enables reducing the viscosity of the electrolyte and suppressing the retention of bubbles generated on the surface of the metal with the anode reaction due to the electropolishing. Furthermore, if the concentration of methanesulfonic acid is equal to or higher than the concentration of phosphoric acid, the viscosity of the electropolishing liquid can be reduced. Since the suppression of the generation of bubbles is effective in the smoothing of the surface of the metal rather than the stabilization of the electrolyte, the electrolyte does not contain additives such as ethylene glycol monoethyl ether, ethylene glycol monobutyl ester, and glycerin for stabilizing the electropolishing liquid.

An organic sulfonic acid such as ethanesulfonic acid, benzenesulfonic acid, p-toluenesulfonic acid, p-phenolsulfonic acid, or vinylsulfonic acid can also be selected instead of methanesulfonic acid.

### (2-2) Electropolishing

The electropolishing of the present disclosure is performed by immersing the stainless steel member in an electropolishing tank filled with the electropolishing liquid described above. The pulse voltage impression, the microaeration, and the electrolyte jetting are adopted. A shaking mechanism for moving the anode vertically and horizontally is adopted. This is because the adoption of the pulse voltage impression, the microaeration, the electrolyte jetting, and the shaking mechanism enables improving the smoothness of the surface of the electropolished stainless steel member and adjusting the height difference measured with a scanning probe microscope to 30 nm or less.

### (2-2-1) Pulse Voltage Impression

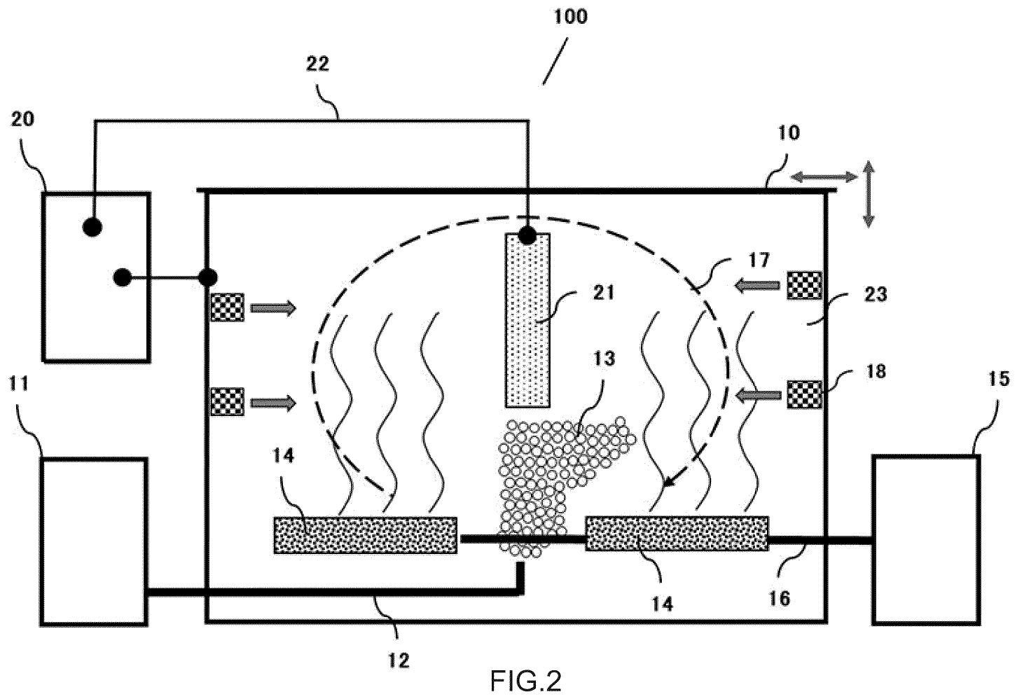

FIG. 2 is a schematic view showing one of the embodiments of an electropolisher 100 for the electropolishing of the present disclosure. In the present embodiment, an electropolishing tank 10 is provided with a pulse voltage generator 20 the ON/OFF of which is controlled by a switching device disposed between a direct current power source as an external power source and a load to perform the electropolishing. A metal 21 to be polished is disposed as an anode and connected to the pulse voltage generator 20 by a lead wire 22. In the present disclosure, the metal 21 to be polished is stainless steel or a stainless steel member.

In the electropolishing of the present disclosure, if the pulse voltage impression in which a voltage having a pulse waveform (square wave) is impressed on the metal 21 to be polished in an electropolishing liquid 23 the current density of which is adjusted to a certain current density during the electrolyzation is adopted, the smoothness of the surface of the metal 21 to be polished can be improved.

FIG. 2 shows the pulse waveform (voltage waveform) in the pulse voltage impression of the present disclosure schematically, and shows the impressed voltage (E+−E0), the voltage application time (Ton), and the voltage halt time (Toff). The repeat cycle of the voltage application time (Ton) and the voltage halt time (Toff) (Tcycle) is 5 to 20 sec. A ratio of 7:3 to 8:2 can be preferably adopted as the ratio of the voltage application time (Ton) to the voltage halt time (Toff). For example, if the repeat cycle (Tcycle) is 10 sec, the voltage application time (Ton) is 7 sec and 8 sec, and the voltage halt time (Toff) is 3 sec and 2 sec, respectively. This is because if the pulse voltage impression is adopted, the impressed voltage (E+−E0) of the metal to be polished is zero (E0) during the voltage halt time (Toff), and a thick and highly dense anolyte layer (Jacquet layer) near the metal to be polished diffuses.

The current density is 10 to 30 A/dm², preferably 10 to 30 A/dm². The electropolishing time (Tall) is 5 to 10 min. The impressed voltage (E+−E0), the voltage application time (Ton), the voltage halt time (Toff), and the electropolishing time (Tall) can be optionally changed depending on the surface roughness of the metal to be polished and the material of the metal to be polished.

### (2-2-2) Anode Shaking Mechanism

Since the electropolisher comprises the anode shaking mechanism by an anode shaking device (not shown), bubbles remaining on the surface to be electropolished can be removed from the surface.

### (2-2-3) Microaeration

An electropolishing liquid 23 exclusively consisting of phosphoric acid and at least one organic sulfonic acid is stored in the electropolishing tank 10 for the electropolishing of the present disclosure. A microbubble generator 11 is disposed on the outer surface of this electropolishing tank 10. A microbubble-conveying pipe 12 is disposed on the inner surface of the electropolishing tank 10. Microbubbles 13 are fed through the microbubble-conveying pipe 12 from the bottom of the electropolishing tank 10. Air diffusers 14 are disposed on the bottom of the electropolishing tank 10. Air fed from a compressor 15 disposed on the outer surface thought the air-conveying pipe 16 disposed on the inner surface is fed from air-diffusing surfaces on which small pores are formed (not shown) as bubbles. The fed microbubbles 13 and the fine bubbles fed from the air diffusers 14 are stirred and circulated in the electropolishing tank 10 as a circulating flow 17. Bubbles remaining on the surface of the metal 21 to be polished with the anode reaction of the electropolishing are removed from the surface of the metal 21 to be polished and prevented from reattaching to the surface of the metal 21 to be polished thereby. Consequently, the bubbles remaining on the surface of the metal 21 to be polished disappear, so that the surface of the metal 21 to be polished is uniformly electropolished to improve the surface smoothness of the metal 21 to be polished.

In order to obtain the action of the microbubbles, microbubbles having different average bubble sizes, namely first microbubbles, having an average bubble size of 10 to 40 μm, and second microbubbles, having an average bubble size of 80 to 150 μm, only have to be added to a desmutting tank. The average bubble size as used here refers to a diameter that the most samples have in the diameter distribution of 2400 microbubbles. This is because the microbubbles having different average bubble sizes are used to improve the desmutting properties. The average bubble size of microbubbles to be added to a desmutting tank is controlled by the amount of bubbles discharged. The amount of the bubbles discharged needs to be controlled to 105 to 150 L/min to add the first microbubbles, having an average bubble size of 10 to 40 μm, and the second microbubbles, having an average bubble size of 80 to 150 μm.

It is preferable that the average bubble size of the microbubbles be in the range of 10 to 150 μm. This is because in the case of less than 10 μm, the bubble generator needs to be large, so that it is difficult to control the bubble size, and in the case of more than 150 μm, the bubble floating speed increases, and the lives of bubbles are shortened in the electropolishing tank 10.

The average bubble size of the microbubbles can be measured with a liquid particle counter or a bubble size distribution measuring apparatus such as an SALD-7100 (SHIMADZU CORPORATION), a Multisizer 4 (Beckman Coulter), or an acoustic bubble size distribution measuring apparatus (West Japan Fluid Engineering Laboratory Co., Ltd.). However, since it is important in the present disclosure to control the generation of the microbubbles having different average bubble sizes, a method involving actually measuring bubble shapes obtained from a still image based on a picture of bubbles generated for a certain period of time by image processing to calculate the average size of 2400 bubbles is adopted.

The present disclosure can use an air diffuser such as a diffuser comprising gas-feeding pipes, an air-diffusing member having air-diffusing surfaces on which small pores are formed and an inner space to be fed with the gas. The air-diffusing member may have any shape, and a tubular air-diffusing pipe comprising an air-diffusing surface on which many uniform small pores are uniformly formed over the entire surface or an air-diffusing plate that is a box-shaped object having one surface that is an air-diffusing surface are usable. It is preferable that the small pores of the air-diffusing surface have a diameter of around 0.3 to 2.0 mm for satisfactory stirring. A circulating flow is generated with the rise of bubbles due to air diffusion to remove bubbles remaining on the metal surface more efficiently. It is preferable that the circulating flow speed be 0.5 to 1.5 m/sec.

### (2-2-4) Electrolyte Jetting

The electrolyte jetting involving applying a jet at a rate of flow of 0.5 to 100 L/min to the surface being electropolished is performed besides the pulse voltage impression and the microaeration. The electrolyte jetting is performed for removing bubbles remaining on the surface being electropolished from the surface similarly to the microaeration. The jet is applied to the surface being electropolished from a jetting nozzle 18.

### 3. Chromium Oxide Film Formation Step

The chromium oxide film formation step has a role of forming the chromium oxide film in which the maximum value of the surface reflectance in the near-infrared region (at a wavelength of 750 to 2500 nm) is 60% or less to reduce the heat radiation rate in the near-infrared region of the stainless steel member.

The chromium oxide film formation step comprises the film formation involving immersing the stainless steel member in the treating liquid comprising the mixed solution of chromic acid and sulfuric acid to form the chromium oxide film on the surface of the stainless steel member and the film hardening involving immersing the chromium oxide film in the treating liquid comprising a mixed solution of chromic acid and phosphoric acid to harden the chromium oxide film.

### (3-1) Film Formation

The so-called INCO process (refer to Japanese Patent Application Laid-Open No. 48-011243), involving forming the chromium oxide film in the mixed solution of chromic acid and sulfuric acid, is adopted for forming the chromium oxide film. The thickness of the chromium oxide film to be formed is controlled by the coloring potential (potential difference between the anode and the reference electrode). The thickness of the chromium oxide film in which the maximum value of the surface reflectance in the near-infrared region (at a wavelength of 750 to 2500 nm) is 60% or less is 190 to 280 nm, and the coloring potential is 17 to 27 mV.

The control of the formation speed of the chromium oxide film (hereinafter referred to as “film formation speed”) enables enhancing the adhesion and the uniformity of the film to suppress the generation of portions having a thin film or film defects (pin holes) that cause the retention of metal impurities to be generated from members for an apparatus for manufacturing a semiconductor or metal impurities contained in semiconductor-treating liquids.

The film formation speed can be controlled by the composition of the treating liquid and the temperature. Regarding the composition of the treating liquid, it is preferable that sulfuric acid is 40 to 50% wt/v to chromic acid of 15 to 30% wt/v. This is because the reduction of the concentration of chromic acid enables reducing the formation speed of the chromium oxide film, functioning as a hydrogen barrier, to control the thickness of the chromium oxide film to be formed precisely. The treating liquid temperature is 60 to 90° C.

The film formation speed can be controlled by the potential speed (mV/sec). The potential speed is 0.002 to 0.08 mV/see, preferably 0.005 to 0.065 mV/sec. This is because if the potential speed is less than 0.002 mV/see, the generation of the chromium oxide film is slowed, resulting in a decrease in productivity. On the other hand, if the potential speed exceeds 0.08 mV/see, the thickness of the chromium oxide film is nonuniform, so that portions having a thin coating film or film defects (pin holes) are generated that cause a deterioration in hydrogen barrier properties.

In order to compensate for the formation speed of the chromium oxide film associated with a decrease of the concentration of chromic acid in the treating liquid, manganese ions (Mn²⁺) can be added. Examples of manganese salts include manganese chloride (MnCl₂), manganese sulfate (MnSO₄), and manganese nitrate (Mn(NO₃)₂). One or more of these can be used. It is preferable that the concentration of manganese ions (Mn²⁺) in the treating liquid is 0.5 to 300 mmol/L, and it is more preferable that the concentration is 5 to 150 mmol/L. This is because if the concentration of manganese ions (Mn²⁺) is less than 0.5 mmol/L, the effect of promoting the formation of the chromium oxide film is absent; and if the concentration of manganese ions (Mn²⁺) exceeds 300 mmol/L, insoluble portions remain to influence the formation of the chromium oxide film.

### (3-2) Hardening

The hardening step has a role of hardening and strengthening the chromium oxide film formed on the surface of the stainless steel subjected to chromium oxide film formation.

In the hardening, the stainless steel member on which the chromium oxide film is formed by the film formation step is disposed as the cathode, and the chromium oxide film is hardened by cathode electrolysis. Around 1011 holes having a size of 10 to 20 nm are distributed per 1 cm2 on the chromium oxide film formed by the film formation step. These holes cause a deterioration in hydrogen barrier properties, and can be filled by the hardening. A loose film can also be strengthened.

Regarding the hardening liquid, it is preferable that phosphoric acid as a reaction accelerator is 0.2 to 0.3% wt/v to chromic acid of 15 to 30% wt/v. The hardening is performed at a current density of 0.2 to 1.0 A/dm² for 5 to 10 min.

### 4. Evaluation of Characteristics

The following characteristics of samples manufactured in Examples and Comparative Examples were evaluated.

### (4-1) Measurement of Surface Roughness

The precisely polished articles were measured for the surface uneven profile through a scanning probe microscope (SFT-4500, manufactured by SHIMADZU CORPORATION) to determine the height difference.

### (4-2) Thickness of Chromium Oxide Film

The thicknesses of the chromium oxide films were measured by the SEM observation of the fractured surface of samples on which the films were formed. The conditions for the SEM observation of the sectional forms were Acceleration voltage: 10.0 kV, Detection mode: Secondary electron detection, and Magnification: 10000 times.

The tones of the chromium oxide films were visually evaluated.

### (4-3) Constituent Element Analysis of Chromium Oxide Films

The elements forming the chromium oxide film layers (Cr, O, and C) were measured by XPS (X-ray photoelectron spectroscopy). An X-ray photoelectron spectroscope (KRATOS AXIS-ultra, manufactured by SHIMADZU CORPORATION) was used. The monochromatic Al Kα line was used as the X-ray source. The irradiation diameter was 30 μm.

Wide scans (qualitative analysis) were performed at a pass energy of 160 eV and an energy step of 1 eV. Narrow scans (quantitative analysis and electron state analysis) were performed at a pass energy of 80 eV and an energy step of 1 eV for Cr 2p, O 2p, C 2p spectra.

### (4-4) Degassing Characteristics

The chromium oxide film-coated stainless steel members were sonicated in acetone (120 seconds) and then introduced into a vacuum chamber to measure times for which the degree of vacuum reached 4.9×10⁻⁵ Pa as the degassing characteristics.

### (4-5) Measurement of Reflectance in Near-Infrared Region

The average reflectances in the near-infrared region (at a wavelength of 750 to 2500 nm) were measured with a spectrophotometer (V-670, manufactured by JASCO Corporation) to determine the maximum reflectances.

### EXAMPLES

Embodiments having the effect of the present disclosure will be shown as Examples. The summary of Examples is shown in Table 1 (the electropolishing conditions and the height difference) and Table 2 (film formation conditions, the maximum reflectance, and degassing properties).

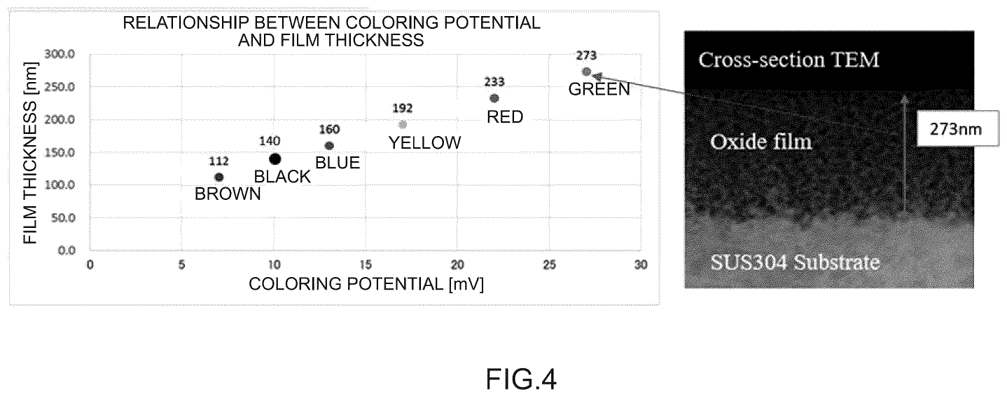

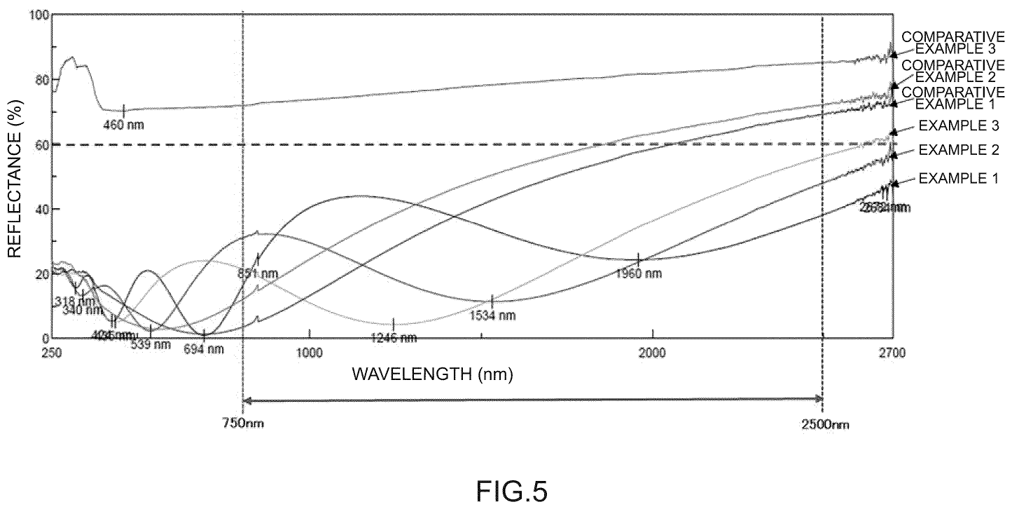

The relationship between the coloring potential and the thickness of the chromium oxide film and a TEM sectional photograph of the green tone are shown in FIG. 4. The spectral reflectance data (at 250 to 2700 nm) of Examples 1 to 3 and Comparative Examples 1 to 3 is shown in FIG. 5.

TABLE 1

| | | | Electropolishing step | | | | |
|---|---|---|---|---|---|---|---|
| | | | Phosphoric | Sulfuric | Methanesulfonic | | |
| | | | acid | acid | acid | | Current |
| | | #400 | (% by | (% by | (% by | Temperature | density |
| | Steel | polishing | volume) | volume) | volume) | (° C.) | (A/dm²) |
| Example 1 | SUS304 | Present | 50 | 0 | 50 | 85 | 20 |
| Example 2 | SUS304 | Present | 50 | 0 | 50 | 85 | 20 |
| Example 3 | SUS304 | Present | 50 | 0 | 50 | 85 | 20 |
| Comparative | SUS304 | Present | 50 | 0 | 50 | 85 | 20 |
| Example 1 | | | | | | | |
| Comparative | SUS304 | Present | 50 | 0 | 50 | 85 | 20 |
| Example 2 | | | | | | | |
| Comparative | SUS304 | Present | 50 | 0 | 50 | 85 | 20 |
| Example 3 | | | | | | | |
| Comparative | SUS304 | Present | 25 | 75 | 0 | 75 | 20 |
| Example 4 | | | | | | | |

| | Electropolishing step | | | | | Characteristic |
|---|---|---|---|---|---|---|
| | | Pulse | | | | Height |
| | Time | voltage | Anode | | | difference |
| | (min) | impression | shaking | Microaeration | Jet | (nm) |
| Example 1 | 5 | Present | Present | Present | Present | 21 |
| Example 2 | 5 | Present | Present | Present | Present | — |
| Example 3 | 5 | Present | Present | Present | Present | 27 |
| Comparative | 5 | Present | Present | Present | Present | — |
| Example 1 | | | | | | |
| Comparative | 5 | Present | Present | Present | Present | — |
| Example 2 | | | | | | |
| Comparative | 5 | Present | Present | Present | Present | — |
| Example 3 | | | | | | |
| Comparative | 5 | Absent | Absent | Absent | Absent | 395 |
| Example 4 | | | | | | |

TABLE 2

| | Film formation | | | | | | | Hardening | | |
|---|---|---|---|---|---|---|---|---|---|---|
| | | Coloring | | | | | | Chromic acid/ | Characteristic | |
| | Chromic acid/ | potential | Coloring | | | | Film | Phosphoric acid | Maximum | Degassing |
| | Sulfuric acid | speed | potential | Temperature | Time | | thickness | (% | reflectance | properties |
| | (% w/vol) | (mV/sec) | (mV) | (° C.) | (min) | Tone | (nm) | w/vol) | (%) | (min) |
| Example 1 | 25/50 | 0.011 | 27 | 65 | 40 | Green | 273 | 25/0.25 | 38.3 | 58 |
| Example 2 | 25/50 | 0.011 | 22 | 65 | 35 | Red | 233 | 25/0.25 | 47.1 | 58 |
| Example 3 | 25/50 | 0.011 | 17 | 65 | 26 | Yellow | 192 | 25/0.25 | 56.1 | 58 |
| Comparative | 15/50 | 0.0024 | 10 | 65 | 70 | Black | 140 | 25/0.25 | 68.9 | 58 |
| Example 1 | | | | | | | | | | |
| Comparative | 25/50 | 0.011 | 7 | 65 | 11 | Brown | 112 | 25/0.25 | 72.2 | 58 |
| Example 2 | | | | | | | | | | |
| Comparative | Absent | | | | | | | Absent | 85.2 | 58 |
| Example 3 | | | | | | | | | | |
| Comparative | Absent | | | | | | | Absent | | 58 |
| Example 4 | | | | | | | | | | |

### Conclusion

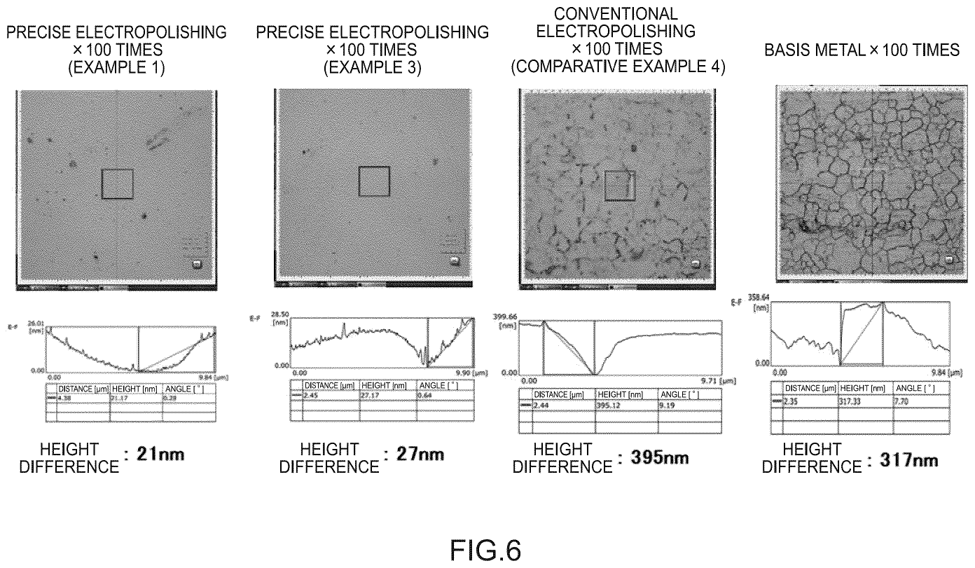

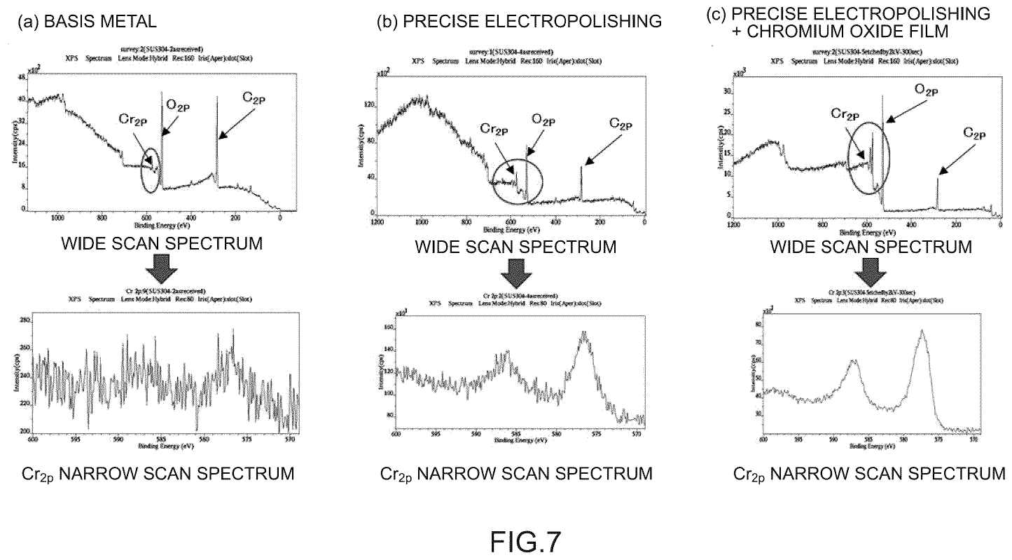

(1) As shown in Table 1 and FIG. 6, in precise electropolishing of the present disclosure in combination with anode shaking, pulse voltage impression, microaeration, and electrolyte jetting in electrolyte of the present disclosure exclusively consisting of phosphoric acid and at least one organic sulfonic acid (Examples 1 and 3), the height differences measured with a scanning probe microscope (SFT-4500, manufactured by SHIMADZU CORPORATION) are 21 nm and 27 nm, respectively. The height differences are significantly small as compared with the height difference in electropolishing in electrolyte comprising phosphoric acid and sulfuric acid (Comparative Example 4), the height difference being 395 nm. The surface of stainless steel on which a chromium oxide film will be formed can be smoothed at the nanometer order to form the chromium oxide film on the surface of the stainless steel uniformly and smoothly.
(2) As shown in Table 2 and FIG. 4, the film thickness of the chromium oxide film is directly proportional to the coloring voltage. As shown in Table 2 and FIG. 5, as the film thickness is thickened, the average reflectance in the near-infrared region (at a wavelength of 750 to 2500 nm) decreases. If the film thickness is 190 to 280 nm, the maximum value of the surface reflectance in the near-infrared region (at a wavelength of 750 to 2500 nm) is 60% or less.
(3) As shown in Table 2, the degassing properties of the chromium oxide film-coated stainless steels (Examples 1 to 3 and Comparative Examples 1 to 2) are equivalent to the degassing properties of the precisely electropolished article (Comparative Example 3) (58 min). Metal impurities can also be controlled at the ppt level in the chromium oxide film-coated article.
(4) As shown in FIG. 7, in surface elemental analysis by X-ray photoelectron spectroscopy, the basis metal (stainless steel) does not have a clear peak of the chromium element (Cr 2p). The basis metal is precisely electropolished and coated with the chromium oxide film to further clarify Cr 2p, O 2p, and C 2p peaks. The chromium oxide film-coated article is coated with chromium oxide having only the Cr 2p, O 2p, and C 2p peaks.

Samples of Examples 1 to 3 and Comparative Examples 1 to 4 were manufactured as follows.

### Example 1

Stainless steel (SUS304, 80×60×2 mm, 2B finish, flat plate) buffed with an abrasive #400 was used as a material to be polished.

### (1) Precise Electropolishing

An electrode (+) was attached to the material to be polished. The material to be polished (stainless steel) was shaken vertically or horizontally with a shaking device and precisely electropolished under the following conditions to manufacture a precisely polished article 1.

### [Electropolishing Conditions]

| Composition of | 50 ml/L phosphoric acid and | |
|---|---|---|
| electropolishing liquid | 50 ml/L methanesulfonic acid | |
| Treatment temperature | 75° | C. |
| Treatment time | 5 | min |
| Current density | 20 | A/dm² |
| Electrolyte jet | 50 | L/min |

### [Pulse Voltage Treatment]

A pulse voltage generator (NC-025025S20X, manufactured by NF Chiyoda Electronics Co., Ltd.) was set at an impressed voltage of 8 V, a repeating period of 10 sec, a voltage application time of 7 sec, and a voltage halt time of 3 sec to add the pulse voltage treatment to the electropolishing.

### [Microaeration]

Microbubbles having an average bubble size of 30 μm and microbubbles having an average bubble size of 100 μm per 2400 counts were generated at a discharge amount (120 L/min) with a microbubble generator (HBKA80-0.251-SDX, manufactured by KANSAI Automation Equipment Co., Ltd.). The average bubble sizes of the microbubbles were measured by image processing (actual measurement in a microbubble image). In addition, bubbles were generated at an air supply speed (100 L/min) from the bottom of the smut treatment tank with a cylindrical air diffuser (manufactured by NISHIDA MACHINERY CO., LTD., size: 70 mm in diameter×1000 mm) to generate a vertical circulating flow in the electropolishing tank. The treatment time was 180 sec.

### (2) Chromium Oxide Film Formation

The polished article 1 was subjected to the film formation (coloring) and the hardening under the following conditions sequentially to manufacture a chromium oxide film-coated article 1.

### [Film Formation Conditions]

| Composition of | 250 g/L chromic acid and | |
|---|---|---|
| coloring liquid | 500 g/L sulfuric acid | |
| Treatment temperature | 65° | C. |
| Treatment time | 40 | min |
| Coloring potential speed | 0.011 | mV/sec |
| Coloring potential | 27 | mV |

### [Hardening Conditions]

| Composition of | 250 g/L chromic acid and | |
|---|---|---|
| hardening liquid | 2.5 g/L phosphoric acid | |
| Treatment temperature | 25° | C. |
| Treatment time | 10 | min |
| Current density | 0.5 | A/dm² |

### Example 2

A precisely polished article 2 and a chromium oxide film-coated article 2 was manufactured similarly to Example 1 except that the chromium oxide film formation was performed under the following conditions.

### (1) Chromium Oxide Film Formation

### [Film Formation Conditions]

| Composition of | 250 g/L chromic acid and | |
|---|---|---|
| coloring liquid | 500 g/L sulfuric acid | |
| Treatment temperature | 65° | C. |
| Treatment time | 35 | min |
| Coloring potential speed | 0.011 | mV/sec |
| Coloring potential | 22 | mV |

### [Hardening Conditions]

| Composition of | 250 g/L chromic acid and | |
|---|---|---|
| hardening liquid | 2.5 g/L phosphoric acid | |
| Treatment temperature | 25° | C. |
| Treatment time | 10 | min |
| Current density | 0.5 | A/dm² |

### Example 3

A precisely polished article 3 and a chromium oxide film-coated article 3 was manufactured similarly to Example 1 except that the chromium oxide film formation was performed under the following conditions.

### (1) Chromium Oxide Film Formation

### [Film Formation Conditions]

| Composition of | 250 g/L chromic acid and | |
|---|---|---|
| coloring liquid | 500 g/L sulfuric acid | |
| Treatment temperature | 65° | C. |
| Treatment time | 26 | min |
| Coloring potential speed | 0.011 | mV/sec |
| Coloring potential | 17 | mV |

### [Hardening Conditions]

| Composition of | 250 g/L chromic acid and | |
|---|---|---|
| hardening liquid | 2.5 g/L phosphoric acid | |
| Treatment temperature | 25° | C. |
| Treatment time | 10 | min |
| Current density | 0.5 | A/dm² |

### Comparative Example 1

A precisely polished article 4 and a chromium oxide film-coated article 4 were manufactured similarly to Example 1 except that the chromium oxide film formation was performed under the following conditions.

### (1) Chromium Oxide Film Formation

### [Film Formation Conditions]

| Composition of | 250 g/L chromic acid and | |
|---|---|---|
| coloring liquid | 500 g/L sulfuric acid | |
| Treatment temperature | 65° | C. |
| Treatment time | 70 | min |
| Coloring potential speed | 0.0024 | mV/sec |
| Coloring potential | 10 | mV |

### [Hardening Conditions]

| Composition of | 250 g/L chromic acid and | |
|---|---|---|
| hardening liquid | 2.5 g/L phosphoric acid | |
| Treatment temperature | 25° | C. |
| Treatment time | 10 | min |
| Current density | 0.5 | A/dm² |

### Comparative Example 2

A precisely polished article 5 and a chromium oxide film-coated article 5 was manufactured similarly to Example 1 except that the chromium oxide film formation was performed under the following conditions.

### (1) Chromium Oxide Film Formation

### [Film Formation Conditions]

| Composition of | 250 g/L chromic acid and | |
|---|---|---|
| coloring liquid | 500 g/L sulfuric acid | |
| Treatment temperature | 65° | C. |
| Treatment time | 11 | min |
| Coloring potential speed | 0.011 | mV/sec |
| Coloring potential | 7 | mV |

### [Hardening Conditions]

| Composition of | 250 g/L chromic acid and | |
|---|---|---|
| hardening liquid | 2.5 g/L phosphoric acid | |
| Treatment temperature | 25° | C. |
| Treatment time | 10 | min |
| Current density | 0.5 | A/dm² |

### Comparative Example 3

Stainless steel (SUS304, 80×60×2 mm, 2B finish, flat plate) buffed with an abrasive #400 was used as a material to be polished.

### (1) Electropolishing

An electrode (+) was attached to the material to be polished. The material to be polished was shaken vertically or horizontally with a shaking device and precisely electropolished under the following conditions to manufacture a precisely polished article 6.

### [Electropolishing Conditions]

| Composition of | 50 ml/L Phosphoric acid and | |
|---|---|---|
| electropolishing liquid | 50 ml/L methanesulfonic acid | |
| Treatment temperature | 75° | C. |
| Treatment time | 5 | min |
| Current density | 20 | A/dm² |
| Electrolyte jet | 50 | L/min |

### [Pulse Voltage Treatment]

A pulse voltage generator (NC-025025S20X, manufactured by NF Chiyoda Electronics Co., Ltd.) was set at an impressed voltage of 8 V, a repeating period of 10 sec, a voltage application time of 7 sec, and a voltage halt time of 3 sec to add the pulse voltage treatment to the electropolishing.

### [Microaeration]

Microbubbles having an average bubble size of 30 μm and microbubbles having an average bubble size of 100 μm per 2400 counts were generated at a discharge amount (120 L/min) with a microbubble generator (HBKA80-0.2S1-SDX, manufactured by KANSAI Automation Equipment Co., Ltd.). The average bubble sizes of the microbubble were measured by image processing (actual measurement in a microbubble image). In addition, bubbles were generated at an air supply speed (100 L/min) from the bottom of the smut treatment tank with a cylindrical air diffuser (manufactured by NISHIDA MACHINERY CO., LTD., size: 70 mm in diameter×1000 mm) to generate a vertical circulating flow in the electropolishing tank. The treatment time was 180 sec.

### Comparative Example 4

Stainless steel (SUS304, 80×60×2 mm, 2B finish, flat plate) buffed with an abrasive #400 was used as a material to be polished.

### (1) Electropolishing

An electrode (+) was attached to the material to be polished. The material to be polished was electropolished under the following conditions to manufacture a polished article 7.

Pulse voltage treatment, microaeration, and electrolyte jetting were not performed. The material to be polished was not shaken vertically or horizontally with a shaking device.

### [Electropolishing Conditions]

| Composition of | 25 ml/L Phosphoric acid and | |
|---|---|---|
| electropolishing liquid | 75 ml/L sulfuric acid | |
| Treatment temperature | 75° | C. |
| Treatment time | 5 | min |
| Current density | 20 | A/dm² |

The present disclosure enables providing stainless steel for an apparatus for manufacturing a semiconductor and a method for manufacturing the stainless steel.

What is claimed is:

1. A chromium oxide film-coated stainless steel member,
wherein a surface of an electropolished stainless steel member is coated with a chromium oxide film,
the surface of the electropolished stainless steel member has the maximum height of a contour curve (Rz) measured with a scanning probe microscope in accordance with JIS B0601-2013 of 30 nm or less,
a film thickness of the chromium oxide film is 190 to 280 nm, and
the maximum value of surface reflectance in the near-infrared region (at a wavelength of 750 to 2500 nm) is 60% or less.

2. A method for manufacturing a chromium oxide film-coated stainless steel member wherein a film thickness of a chromium oxide film is 190 to 280 nm, and the maximum value of surface reflectance in the near-infrared region (at a wavelength of 750 to 2500 nm) is 60% or less, comprising:
an electropolishing step of electropolishing a surface of a stainless steel member with an electropolishing liquid for stainless steel at 85° C. exclusively consisting of 50% by volume phosphoric acid and 50% by volume methanesulfonic acid at a current density of 20 A/dm² for 5 minutes in combination with pulse voltage impression, microaeration, and electrolyte jetting to adjust the maximum height of a contour curve (Rz) measured with a scanning probe microscope in accordance with JIS B0601-2013 to 30 nm or less; and
a step of coating the stainless steel member with a chromium oxide film, comprising:
film formation involving immersing the electropolished stainless steel member in a treating liquid comprising a mixed solution of 25% w/vol chromic acid and 50% w/vol sulfuric acid to form a chromium oxide film on the surface of the stainless steel member at a coloring potential of 17 to 28 mV, and
hardening involving immersing the coated stainless steel member in a treating liquid comprising a mixed solution of chromic acid and phosphoric acid to harden the chromium oxide film.
